(19) United States
(12) Patent Application Publication
(10) Pub. No.: US 2025/0301837 A1
(43) Pub. Date: Sep. 25, 2025

(54) MANUFACTURING METHOD FOR LIGHT-EMITTING DEVICE

(71) Applicant: STANLEY ELECTRIC CO., LTD., Tokyo (JP)

(72) Inventors: Kenji TABUCHI, Meguro-ku (JP); Kodai SHIINA, Meguro-ku (JP); Yusuke YAMASHITA, Meguro-ku (JP); Hiroki SAWADA, Meguro-ku (JP); Nobumichi AITA, Meguro-ku (JP)

(73) Assignee: STANLEY ELECTRIC CO., LTD., Tokyo (JP)

(21) Appl. No.: 19/075,805

(22) Filed: Mar. 11, 2025

(30) Foreign Application Priority Data
Mar. 22, 2024 (JP) 2024-047130

(51) Int. Cl. H10H 29/01; H01L 25/075

(52) U.S. Cl. CPC H10H 29/0361; H01L 25/0753; H10H 29/0363

(57) ABSTRACT

Provided is a manufacturing method for a light-emitting device that can improve yield during manufacturing while achieving wide-angle light distribution. A manufacturing method for a light-emitting device includes: a preparing step of preparing a substrate having an upper surface on which a plurality of light-emitting elements are disposed, each of the plurality of light-emitting elements including a light-emitting layer; a phosphor layer forming step of forming a phosphor layer by pouring a first precursor made of a resin in which phosphor particles are dispersed onto the upper surface of the substrate and heat-curing the poured first precursor, the phosphor layer encompassing the plurality of light-emitting elements; a trench forming step of forming a trench on an upper surface of the phosphor layer to separate each of the light-emitting elements in a top view from a direction perpendicular to the upper surface; a sealing layer forming step of forming a sealing layer by pouring a second precursor made of a translucent resin onto the upper surface of the phosphor layer and heat-curing the poured second precursor; a transmissive-reflective layer forming step of forming a transmissive-reflective layer on the sealing layer, the transmissive-reflective layer partially reflecting and partially transmitting each of a light emitted from the light-emitting layer and a fluorescence emitted from the phosphor layer; and an individualizing step of individualizing the light-emitting device by cutting from an upper surface of the transmissive-reflective layer to the substrate along the trench in depth direction.

### BACKGROUND

### 1. Technical Field

This invention relates to a manufacturing method for a light-emitting device that includes a light-emitting element.

### 2. Description of the Related Art

A light-emitting device including a phosphor layer, which includes a light-emitting element, covered with a transparent resin layer is disclosed. For example, JP-A-2022-162976 discloses a light-emitting device that includes a light-emitting element arranged on a substrate, a color conversion package containing color conversion particles formed to house the light-emitting element on the substrate, and a transparent package made of a resin that covers the entire color conversion package.

When manufacturing the light-emitting device disclosed in JP-A-2022-162976, for example, when using a dicer to individually separate the color conversion package into each light-emitting device after forming the color conversion package, there is a possibility that a blade of the dicer might reach the substrate.

If the blade of the dicer reaches the substrate when the color conversion package is being separated as described above, the substrate is likely to become bent, and there is a possibility that the color conversion package could peel off the substrate or that the wiring formed on the substrate will break. If this happens, a yield when manufacturing the light-emitting device decreases.

In the light-emitting device disclosed in JP-A-2022-162976, the radiated light has a Lambertian light distribution. Therefore, in environments where light with a wider-angle light distribution than the Lambertian light distribution is required, such as a light source for auxiliary lights for a vehicle, it might not be possible to use a light-emitting device such as the one disclosed in JP-A-2022-162976 as a light source.

The present invention is made in consideration of the above-described problems, and it is an object of the present invention to provide a manufacturing method for a light-emitting device that can improve yield during manufacturing while achieving wide-angle light distribution.

### SUMMARY OF THE INVENTION

A manufacturing method for a light-emitting device according to the present invention includes: a preparing step of preparing a substrate having an upper surface on which a plurality of light-emitting elements are disposed, each of the plurality of light-emitting elements including a light-emitting layer; a phosphor layer forming step of forming a phosphor layer by pouring a first precursor made of a resin in which phosphor particles are dispersed onto the upper surface of the substrate and heat-curing the poured first precursor, the phosphor layer encompassing the plurality of light-emitting elements; a trench forming step of forming a trench on an upper surface of the phosphor layer to separate each of the light-emitting elements in a top view from a direction perpendicular to the upper surface; a sealing layer forming step of forming a sealing layer by pouring a second precursor made of a translucent resin onto the upper surface of the phosphor layer and heat-curing the poured second precursor; a transmissive-reflective layer forming step of forming a transmissive-reflective layer on the sealing layer, the transmissive-reflective layer partially reflecting and partially transmitting each of a light emitted from the light-emitting layer and a fluorescence emitted from the phosphor layer; and an individualizing step of individualizing the light-emitting device by cutting from an upper surface of the transmissive-reflective layer to the substrate along the trench in depth direction.

### BRIEF DESCRIPTION OF THE DRAWINGS

FIG. 1 is a top view of a light-emitting device according to Embodiment 1;

FIG. 2 is a bottom view of the light-emitting device according to Embodiment 1;

FIG. 3 is a cross-sectional view of the light-emitting device according to Embodiment 1;

FIG. 4 is a cross-sectional view of the light-emitting device according to Embodiment 1;

FIG. 5 is a table showing a result of a validation for the light-emitting device in Embodiment 1;

FIG. 6 is a cross-sectional view illustrating a manufacturing step of a first manufacturing method for the light-emitting device in Embodiment 1;

FIG. 7 is a cross-sectional view illustrating a manufacturing step of the first manufacturing method for the light-emitting device in Embodiment 1;

FIG. 8 is a cross-sectional view illustrating a manufacturing step of the first manufacturing method for the light-emitting device in Embodiment 1;

FIG. 9 is a cross-sectional view illustrating a manufacturing step of the first manufacturing method for the light-emitting device in Embodiment 1;

FIG. 10 is a cross-sectional view illustrating a manufacturing step of a second manufacturing method for the light-emitting device in Embodiment 1;

FIG. 11 is a cross-sectional view illustrating a manufacturing step of the second manufacturing method for the light-emitting device in Embodiment 1;

FIG. 12 is a cross-sectional view illustrating a manufacturing step of the second manufacturing method for the light-emitting device in Embodiment 1;

FIG. 13 is a cross-sectional view illustrating a manufacturing step of the second manufacturing method for the light-emitting device in Embodiment 1; and

FIG. 14 is a cross-sectional view illustrating a manufacturing step of the second manufacturing method for the light-emitting device in Embodiment 1.

### DETAILED DESCRIPTION

The following is a detailed description of embodiments of this invention, with reference to the drawings. In the drawings, the same reference numerals are given to substantially same or equivalent parts, and the description of the components that are repeated is omitted.

### Embodiment 1

### [Outline of Light-Emitting Device 100]

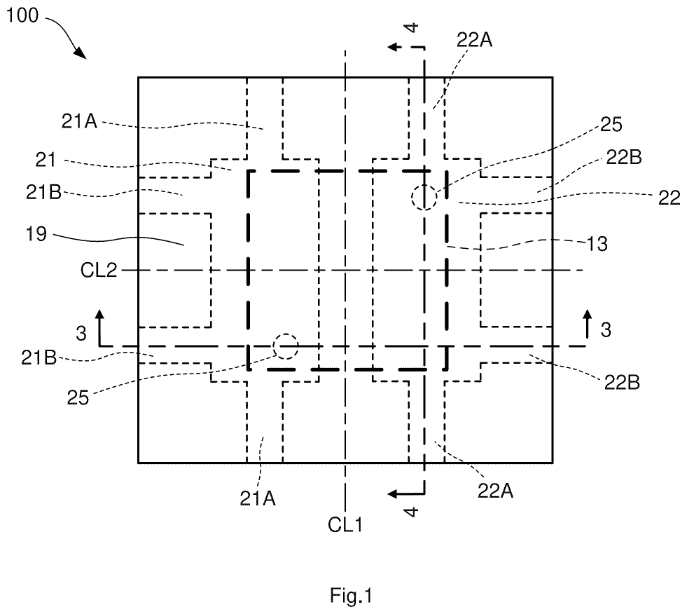

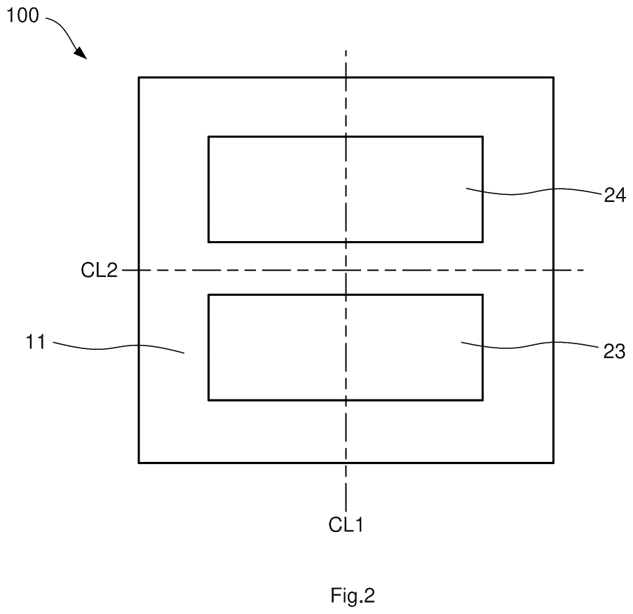

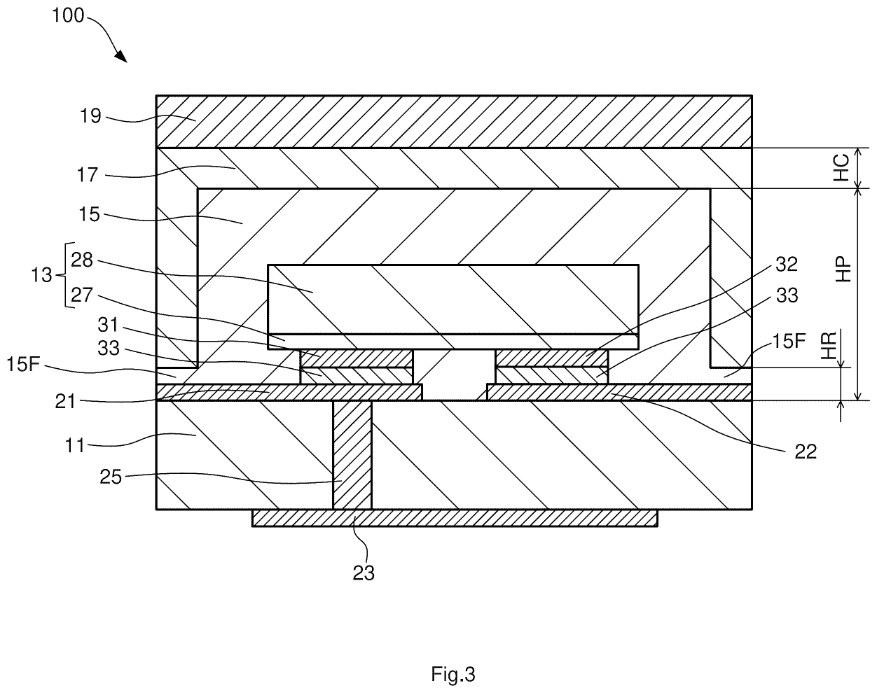

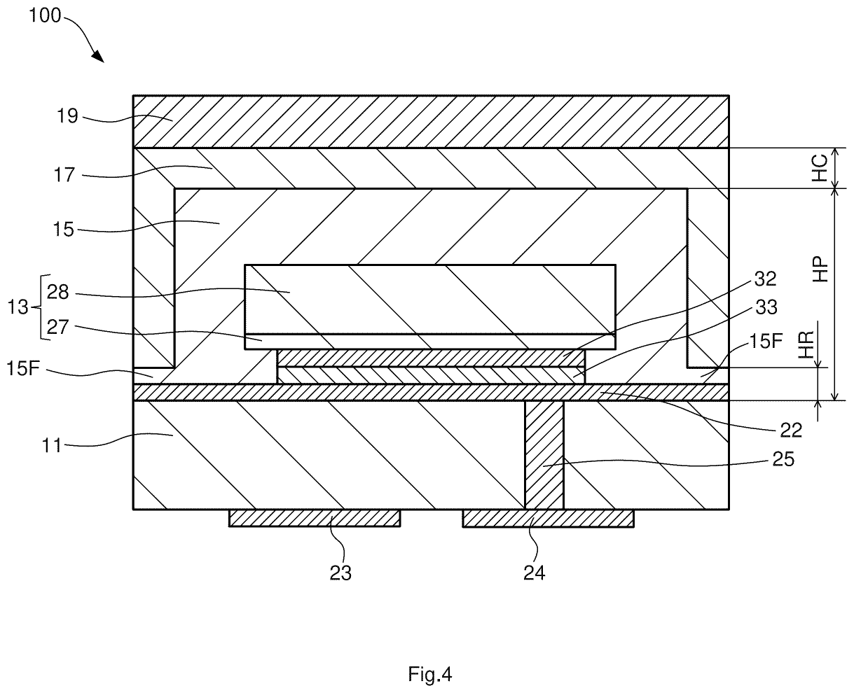

A structure of a light-emitting device 100 according to Embodiment 1 is described using FIGS. 1 to 4. FIG. 1 is a top view of the light-emitting device 100 of according to Embodiment 1. FIG. 2 is a bottom view of the light-emitting device 100 according to Embodiment 1. FIG. 3 is a cross-sectional view of the light-emitting device 100 in FIG. 1 along the 3-3 line. FIG. 4 is a cross-sectional view of the light-emitting device 100 in FIG. 1 along the 4-4 line.

In FIGS. 1 and 2, the center line (a line dividing into two) of a width direction (a left-right direction in the figure) of the light-emitting device 100 is illustrated as the center line CL1 by a dash-dot line, and the center line (a line dividing into two) of the depth direction (an up-down direction in the figure) of the light-emitting device 100 is illustrated as the center line CL2 by a dash-dot line.

In FIG. 3, the left-right direction in the figure is the width direction of the light-emitting device 100, and the top-bottom direction in the figure is a height direction of the light-emitting device 100. In FIG. 4, the left-right direction in the figure is the depth direction of the light-emitting device 100, and the top-bottom direction in the figure is the height direction of the light-emitting device 100.

The light-emitting device 100 is configured to include a substrate 11, a light-emitting element 13 provided above the substrate 11, a phosphor layer 15 formed above the substrate 11 to cover the light-emitting element 13, a sealing layer 17 formed to cover the phosphor layer 15, and a transmissive-reflective layer 19 formed over an upper surface of the sealing layer 17, as illustrated in FIGS. 3 and 4.

### [Substrate 11]

First, the substrate 11 is described. The substrate 11 is a flat plate-shaped glass epoxy substrate (FR-4) with a rectangular upper surface shape and has an insulating property. In addition, a ceramic substrate made of alumina (Al₂O₃) or aluminum nitride (AlN) may be used for the substrate 11. On an upper surface of the substrate 11, an anode pad 21 and a cathode pad 22 are formed. On a lower surface of substrate 11, an anode electrode 23 and a cathode electrode 24 are formed.

The anode pad 21 and the cathode pad 22 are a pair of element mounting pads each having an oblong upper surface shape. The pair of element mounting pads are separated from each other so as to sandwich the center line CL1 formed on the upper surface of the substrate 11.

The anode pad 21 has two extensions 21A that extend from of respective short sides along the center line CL1 and reach the outer edge of the substrate 11. The anode pad 21 has two extensions 21B that extend from one long side along the center line CL2 so as to sandwich the center line CL2, and reach the outer edge of the substrate 11.

Similarly to the anode pad 21, the cathode pad 22 has two extensions 22A that extend from of respective short sides along the center line CL1 and reach the outer edge of the substrate 11. The cathode pad 22 has two extensions 22B that extend from one long side along the center line CL2 so as to sandwich the center line CL2, and reach the outer edge of the substrate 11.

The anode electrode 23 and the cathode electrode 24 are a pair of electrodes each having an oblong upper surface shape. The pair of electrodes are separated from each other so as to sandwich the center line CL2 on the lower surface of the substrate 11. In the light-emitting device 100, in a top view of the substrate 11 viewed from above, longitudinal directions of the anode pad 21 and the cathode pad 22 are orthogonal to longitudinal directions of the anode electrode 23 and the cathode electrode 24.

Each of the anode pad 21, the cathode pad 22, the anode electrode 23, and the cathode electrode 24 is made of copper (Cu) material, and has a nickel (Ni) plating and a gold (Au) plating applied to a surface thereof in this order. For the plating process, silver (Ag) plating may be used instead of Au plating.

In the light-emitting device 100, the anode pad 21 and the anode electrode 23 are electrically connected via a conductive via 25 made of a Cu material. Similarly, the cathode pad 22 and the cathode electrode 24 are electrically connected via a conductive via 25.

### [Light-Emitting Element 13]

Next, the light-emitting element 13 is described. As described above, the light-emitting element 13 is arranged on the upper surface of the substrate 11, and is a light-emitting diode (LED) having a rectangular upper surface shape.

As illustrated in FIGS. 3 and 4, the light-emitting element 13 is configured to include a semiconductor structure layer 27 having a light-emitting layer made of a semiconductor, and a light-transmitting substrate 28 having a translucency arranged on an upper surface of the semiconductor structure layer 27.

The semiconductor structure layer 27 is a semiconductor layered structure constituted of an n-type semiconductor layer, a light-emitting layer, and a p-type semiconductor layer (not illustrated), each of which is mainly made of gallium nitride (GaN). When the light-emitting element 13 is driven, a blue light with a peak wavelength of 450 nm is radiated from the light-emitting layer of the semiconductor structure layer 27.

The light-transmitting substrate 28 is a flat plate-shaped substrate having a rectangular upper surface shape. The light-transmitting substrate 28 is made of a material having a translucency to the blue light emitted from the light-emitting layer of the semiconductor structure layer 27, such as sapphire (Al₂O₃) or GaN, and to a fluorescence emitted from the phosphor layer 15 described below. The light-transmitting substrate 28 is also a substrate for growing the semiconductor structure layer 27.

The light-emitting element 13 include a p-electrode 31 and an n-electrode 32 each formed on a lower surface of the semiconductor structure layer 27 and has an oblong upper surface shape. The p-electrode 31 is an electrode electrically connected to the p-type semiconductor layer of the semiconductor structure layer 27. The p-electrode 31 is plated with gold (Au) on a surface thereof.

The n-electrode 32 is an electrode that is electrically connected to the n-type semiconductor layer via a through-electrode (not illustrated) that penetrates the light-emitting layer and the p-type semiconductor layer of the semiconductor structure layer 27 in a vertical direction and has a side surface covered with an insulator. In other words, the n-electrode 32 is electrically connected only to the n-type semiconductor layer and is insulated from the light-emitting layer and the p-type semiconductor layer. The n-electrode 32 is plated with Au on a surface thereof.

The p-electrode 31 and the n-electrode 32 are respectively connected to the anode pad 21 and the cathode pad 22 via epoxy resin solders 33. In other words, in the light-emitting device 100, the light-emitting element 13 is flip-chip mounted on the substrate 11.

The epoxy resin solder 33 contains tin-silver-copper (Sn—Ag—Cu) and other solder metal particles in an epoxy resin flux, and after bonding, the epoxy resin covers an area around a solder joint to increase a bonding strength thereof. Also, since the area around the solder joint is covered with the epoxy resin, an adhesion with the phosphor layer 15 is improved, which is preferred. As the epoxy resin solder 33, a gold-tin (Au—Sn) solder using volatile flux may be used.

### [Phosphor Layer 15]

Next, the phosphor layer 15 is described. The phosphor layer 15 has a rectangular upper surface shape and is provided on the substrate 11 to encompass the light-emitting element 13. The phosphor layer 15 includes a frame-shaped portion 15F that protrudes laterally from a lower end of the side surface along the upper surface of the substrate 11 and is continuously formed around a periphery of the phosphor layer 15 in a top view. The frame-shaped portion 15F extends from the lower end of the side surface of the phosphor layer 15 to the outer edge of the substrate 11.

The phosphor layer 15 includes a phosphor that emits a fluorescence when excited by the blue light radiated from the light-emitting element 13 as an excitation light. When excited by the blue light, the phosphor layer 15 emits a green fluorescence with a peak wavelength in a wavelength range of 500 to 580 nm and a red fluorescence with a peak wavelength in a wavelength range of 620 to 640 nm.

The phosphor layer 15 is constituted of KSF (K₂SiF₆:Mn) phosphor particles that emit a red fluorescence and a β-Sialon phosphor particles that emit a green fluorescence, which are dispersed in the translucent resin, such as a silicone resin.

When the blue light radiated from the light-emitting element 13 enters the phosphor layer 15, a part thereof passes through the phosphor layer 15 as it is, and a part thereof excites the phosphor particles, causing the fluorescence to be emitted from the excited phosphor particles.

Therefore, from the upper surface of the phosphor layer 15, the excitation light (the blue light), which has passed through the phosphor layer 15 without contributing to generation of the fluorescence, and the fluorescence (the green light and the red light), which is emitted from the phosphor particles, are radiated. As a result, a white light that is a mixture of the blue light, the red fluorescence, and the green fluorescence is taken out from the upper surface of the phosphor layer 15.

### [Sealing Layer 17]

Next, the sealing layer 17 is described. The sealing layer 17 is a translucent layer that covers the upper surface of the phosphor layer 15, extends from the side surface upper end of the phosphor layer 15 to cover the side surface, and terminates at an upper surface of the frame-shaped portion 15F. The sealing layer 17 is made of a silicone resin that transmits the white light (specifically, a white band light).

The sealing layer 17 covers most of the phosphor layer 15 to function as a protective layer that protects a KSF Phosphor, which is easily altered by moisture, from outside air. The sealing layer 17 also functions as a light-guiding layer that guides the white light emitted from the phosphor layer 15.

### [Transmissive-Reflective Layer 19]

Next, the transmissive-reflective layer 19 is described. As described above, the transmissive-reflective layer 19 is formed over the upper surface of the sealing layer 17, and is a layer that reflects a part of the white light propagated and emitted through the sealing layer 17 while transmitting a part thereof.

In the light-emitting device 100 of the embodiment, the transmissive-reflective layer 19 is a dielectric multilayer film whose layer thickness is adjusted such that the reflectivity for the white light becomes a predetermined value. The dielectric multilayer film is suitable for controlling a light distribution property (a directional property) because it generates transmitted and reflected light without attenuating an incident light. In the light-emitting device 100, the transmissive-reflective layer 19 is made up of, for example, 10 to 40 layers (5 to 20 pairs) of alternating silicon oxide (SiO₂) and alumina (Al₂O₃).

A material for the transmissive-reflective layer 19 may be a combination of titanium dioxide (TiO₂), niobium oxide (NbO), magnesium oxide (MgO), tantalum oxide (Ta₂O₅), hafnium oxide (HfO), and the like.

In the light-emitting device 100 of the embodiment, the reflectivity of the transmissive-reflective layer 19 for the white light is set to 60%. As a result, the light radiated from the light-emitting device 100 has a light distribution known as a batwing light distribution, in which the light intensity is suppressed directly above the light-emitting device 100 while the light intensity on the side is increased. In other words, the light radiated from the light-emitting device 100 has a wider-angle light distribution (a half-angle 140° to) 180° than the Lambertian light distribution (a half-angle) 120°, where the light intensity decreases from directly above the light-emitting device 100 to the sides.

The light-emitting device 100 having a batwing light distribution like this can be used in environments where light with a high degree of uniformity in luminance distribution over a wide range is required, such as a light source for auxiliary lights for vehicles or a light source for direct-type backlights for LCD TVs.

The phosphor layer 15 of the light-emitting device 100 of the embodiment includes the frame-shaped portion 15F continuously formed around the periphery of the phosphor layer 15 as described above. For example, when the phosphor layer 15 is separated into individual light-emitting devices using a dicer during the manufacture of the light-emitting device 100, the yield during manufacture can be improved by processing the phosphor layer 15 such that the frame-shaped portion 15F is left (details will be described later).

### [Verification]

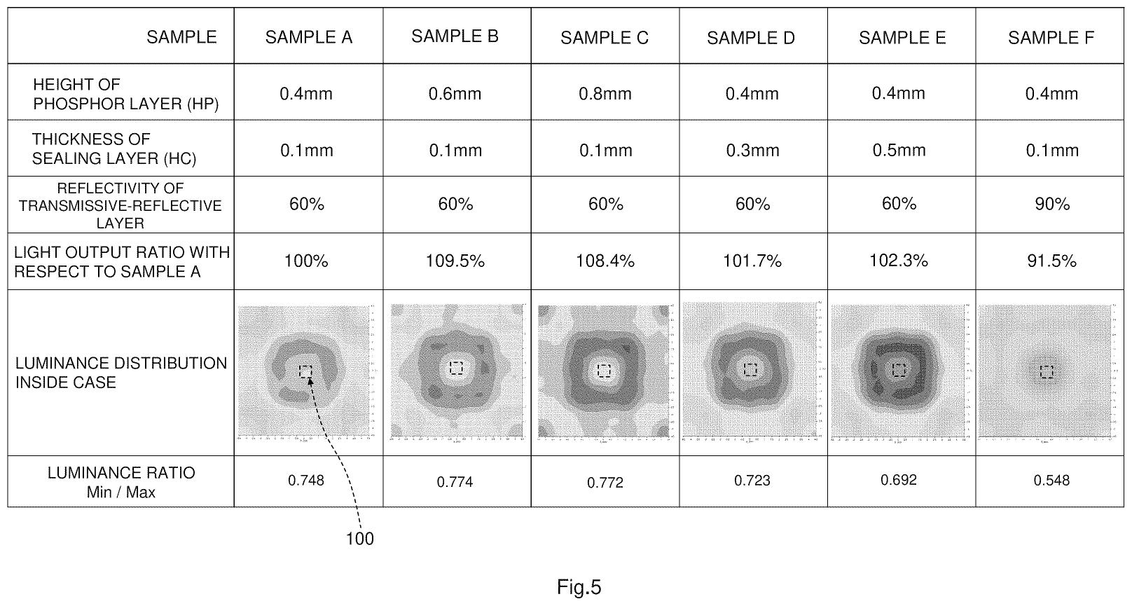

Here, using FIGS. 3 to 5, it is described that details of the verification and results of the verification conducted on the light-emitting device 100 of the embodiment. FIG. 5 is a table showing optical output ratio, luminance distribution, and luminance ratio (minimum luminance/maximum luminance) calculated by measuring the optical output and the luminance of each of the six Samples A to F based on the configuration of the light-emitting device 100.

In FIG. 5, each of Samples B to F differs from Sample A as a reference in either a height HP of the phosphor layer 15 from the upper surface of the substrate 11, a thickness HC of the sealing layer 17 from the upper surface of the phosphor layer 15 (see FIGS. 3 and 4), or a reflectivity of the transmissive-reflective layer 19 for the white light. A thickness of the frame-shaped portion 15F from the upper surface of the substrate 11 is defined as a thickness HR.

In this verification, a measurement module in which each of 1 mm square Samples A to F arranged in the center of a 9 mm square white case having an opening at a top thereof is used. In this verification, the white cases with one sample arranged therein are lined up in a 3×3 pattern with no gaps, and an optical output and a luminance of each sample are measured using the radiated light from the one white case in the center thereof.

The “luminance distribution within the case” in the table in FIG. 5 shows the luminance distribution when looking down on the white case in which each of the Samples A to F is placed, and indicates that the darker the color, the higher the luminance. For example, in Sample A, it can be found that the luminance around the light-emitting device 100 is the highest.

In addition, the “luminance ratio” in the table in FIG. 5 indicates that the closer the value is to 1, the more uniform the luminance of the light within the white case. In other words, the higher the luminance ratio, the more evenly the light is distributed within the white case.

### [Comparison of Samples A, B, and C]

Samples A, B, and C differ only in the height HP of the phosphor layer 15 (0.4 mm, 0.6 mm, and 0.8 mm, respectively), while the thickness HC of the sealing layer 17 (0.1 mm) and the reflectivity (60%) of the transmissive-reflective layer 19 are mutually the same.

As illustrated in FIG. 5, the optical output ratio has improved to 109.5% for Sample B and 108.4% for Sample C, compared with 100% for Sample A. The luminance ratio has also improved, from 0.748 for Sample A to 0.774 for Sample B and 0.772 for Sample C. In other words, both the optical output ratio and the luminance ratio are better for Samples B and C than for Sample A.

### [Comparison of Samples A, D, and E]

Samples A, D, and E differ only in the thickness HC of the sealing layer 17 (0.1 mm, 0.3 mm, and 0.5 mm, respectively), while the height HP of the phosphor layer 15 (0.4 mm) and the reflectivity of the transmissive-reflective layer 19 (60%) are mutually the same.

As illustrated in FIG. 5, the optical output ratio of Sample D is 101.7% and the optical output ratio of Sample E is 102.3% when setting sample A as 100%. However, the luminance ratio has decreased to 0.723 for Sample D and 0.692 for Sample E, compared with 0.748 for Sample A. In other words, while Samples D and E are superior to Sample A in terms of the optical output ratio, Samples D and E are inferior to Sample A in terms of the luminance ratio.

### [Comparison of Samples A and F]

The only difference between Samples A and F is the reflectivity of the transmissive-reflective layer 19 (60% and 90%, respectively), while the height HP (0.4 mm) of the phosphor layer 15 and the thickness HC (0.1 mm) of the sealing layer 17 are mutually the same.

As illustrated in FIG. 5, the optical output ratio of Sample F is 91.5%, which is lower than the 100% of Sample A. In addition, the luminance ratio of Sample F is 0.548, which is lower than the 0.748 of Sample A. In other words, both the optical output ratio and the luminance ratio of Sample F are lower than those of Sample A.

### [Summary of Verification]

From the comparison of Samples A, B, and C, it is preferred that the height HP of the phosphor layer 15 from the upper surface of the substrate 11 in the light-emitting device 100 having a 1 mm square is 0.6 mm to 0.8 mm. In other words, it is preferred that the height HP of the phosphor layer 15 is 60% to 80% of the length of one side of the transmissive-reflective layer 19 when looking down on the light-emitting device 100.

In addition, based on the comparison results for Samples A, D, and E, for the light-emitting device 100 having the 1 mm square, it is preferred that the thickness HC of the sealing layer 17 from the upper surface of the phosphor layer 15 is 0.1 mm from the perspective of achieving wide-angle light distribution with the light-emitting device 100. In other words, it is preferred that the height HP of the phosphor layer 15 is 10% of the length of one side of the transmissive-reflective layer 19 when looking down on the light-emitting device 100.

In addition, based on the comparison results for Samples A and F, it is preferred that the reflectivity of the transmissive-reflective layer 19 for the white light is 60% in the light-emitting device 100 having the 1 mm square. When the reflectivity of the transmissive-reflective layer 19 falls below 50%, the central luminance of the white case increases, and the luminance ratio decreases. Similarly, when the reflectivity of the transmissive-reflective layer 19 exceeds 70%, the central luminance of the white case decreases, and the luminance ratio decreases. In other words, the reflectivity of 60±10% is preferred for the transmissive-reflective layer 19, and 60±5% is further preferred.

As illustrated above, the light-emitting device 100 of the embodiment can radiate the light with the wide-angle light distribution from the light-emitting device 100.

In the embodiment, it is described that the light radiated from the light-emitting device 100 has the batwing light distribution, but it is sufficient when the light radiated from the light-emitting device 100 has the wide-angle light distribution, and it does not necessarily need to have the batwing light distribution.

For example, the reflectivity of the transmissive-reflective layer 19 in the light-emitting device 100 for the white light may be made lower than 60%. This makes it possible to obtain an umbrella-shaped light distribution, or so-called umbrella light distribution, as a whole, by making the optical output from directly above the light-emitting device 100 increase compared with the batwing light distribution and then gradually weaken as it moves laterally.

### [Modification of Light-Emitting Device 100]

Next, a modification of Embodiment 1 is described. In this modification, the configuration of the transmissive-reflective layer 19 differs from Embodiment 1, but the configuration of other parts, such as the phosphor layer 15 and the sealing layer 17, are the same as in Embodiment 1.

In this modification, the transmissive-reflective layer 19 is configured by dispersing yttrium phosphate (YPO₄) particles with a particle diameter of 1 to 5 nm in silicone resin. The YPO₄ particles have a weaker backscattering property than titanium dioxide (TiO₂) particles or alumina (Al₂O₃) particles, which scatter a light in the direction opposite to the incident direction, and have a superior forward scattering property, which scatter the light in the same direction as the incident direction of the light.

Therefore, the white light that enters the transmissive-reflective layer 19 of the modification from the sealing layer 17 is radiated after being widely scattered in the outward direction of the transmissive-reflective layer 19 (the top direction in FIGS. 3 and 4). In addition, while suppressing the attenuation of the light within the transmissive-reflective layer 19 due to backscattering, it is possible to create a so-called reverse umbrella light distribution, which is a reverse triangular shaped light distribution that increases the optical output of the central part of the batwing light distribution or the batwing light distribution.

Even when the configuration of the transmissive-reflective layer 19 is changed in this way, the light-emitting device 100 of the modification can radiate the light with the wide-angle light distribution similarly to the light-emitting device 100 of Embodiment 1.

### [First Manufacturing Method for Light-Emitting Device 100]

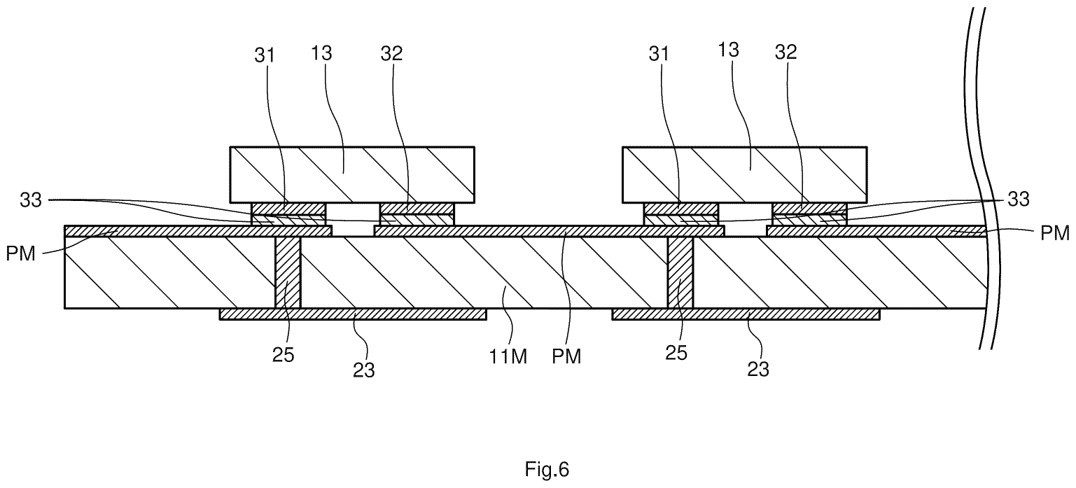

The first manufacturing method for the light-emitting device 100 is described below using FIGS. 6 to 10. FIGS. 6 to 10 are cross-sectional views illustrating steps of the first manufacturing method for the light-emitting device 100. FIGS. 6 to 10 illustrate partial cross-sectional views of a substrate assembly 11M, which has a plurality of light-emitting elements 13 arranged on an upper surface thereof, as an example.

First, the substrate assembly 11M with various wirings is prepared (Step 1: a substrate preparing step). Specifically, as illustrated in FIG. 6, the substrate assembly 11M is prepared. In the substrate assembly 11M, a pad body PM before formation (before cutting) of the anode pad 21 and the cathode pad 22 is patterned on an upper surface thereof, the anode electrode 23 and the cathode electrode 24 are patterned on a lower surface thereof, and conductive vias 25 are formed to electrically connect the pad body PM to the anode electrode 23 and the cathode electrode 24.

Next, as illustrated in FIG. 6, each of the plurality of light-emitting elements 13 is mounted on the upper surface of the substrate assembly 11M (Step 2: an element mounting step). Specifically, the epoxy resin solder 33 is applied to the pad body PM, and the light-emitting element 13 is placed on the applied epoxy resin solder 33. The light-emitting element 13 is then mechanically and electrically bonded to the pad body PM by heating it at 250° C. for 0.5 minutes, and then holding it at 150° C. for 2 hours.

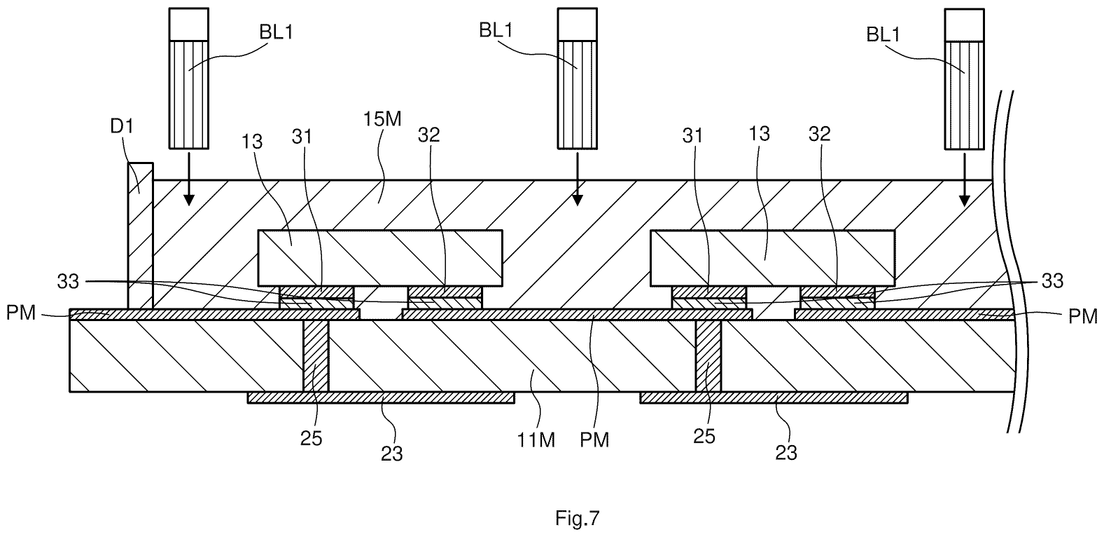

Next, a phosphor layer 15M is formed on the substrate assembly 11M to encompass the respective plurality of light-emitting elements 13 (Step 3: a phosphor layer forming step). Specifically, as illustrated in FIG. 7, a frame-shaped first dam structure D1 made of a resin is formed on the upper surface of the substrate assembly 11M along an outer edge of the substrate assembly 11M, and a predetermined amount of a first precursor resin to be the phosphor layer 15M is poured inside the first dam structure D1. After that, the first precursor resin is allowed to settle such that it becomes smooth, and then the phosphor layer 15M is formed by heating and curing at 150° C. for 120 minutes. The method of pouring the precursor resin into the dam structure and then heat-curing the precursor resin is called “pouring and molding.”

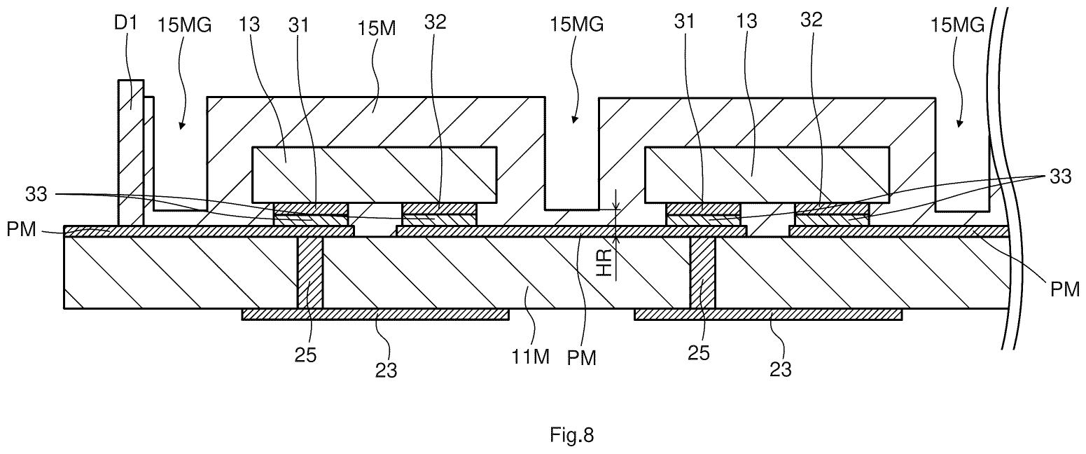

Next, separation trenches are formed on the upper surface of the phosphor layer 15M such that the substrate assembly 11M is separated into each of the plurality of light-emitting elements 13 in a top view from above (Step 4: a trench forming step). Specifically, the separation trenches 15MG are formed to separate each of the plurality of light-emitting elements 13 as illustrated in FIG. 8 using the dicing blade BL1 of the dicer illustrated in FIG. 7.

At this time, the separation trenches 15MG are formed such that a remaining portion is left with a thickness HR from the upper surface of the substrate assembly 11M. The above-described frame-shaped portion 15F of the light-emitting device 100 is the remaining portion of these separation trenches 15MG. The remaining portion is provided such that a wide cutting edge of the dicing blade BL1 does not come into contact with the upper surface of the substrate assembly 11M. This is because the wide cutting edge of the dicing blade BL1 causes the substrate assembly 11M to bend, resulting in peeling of the phosphor layer 15 or breaking of the light-emitting element 13.

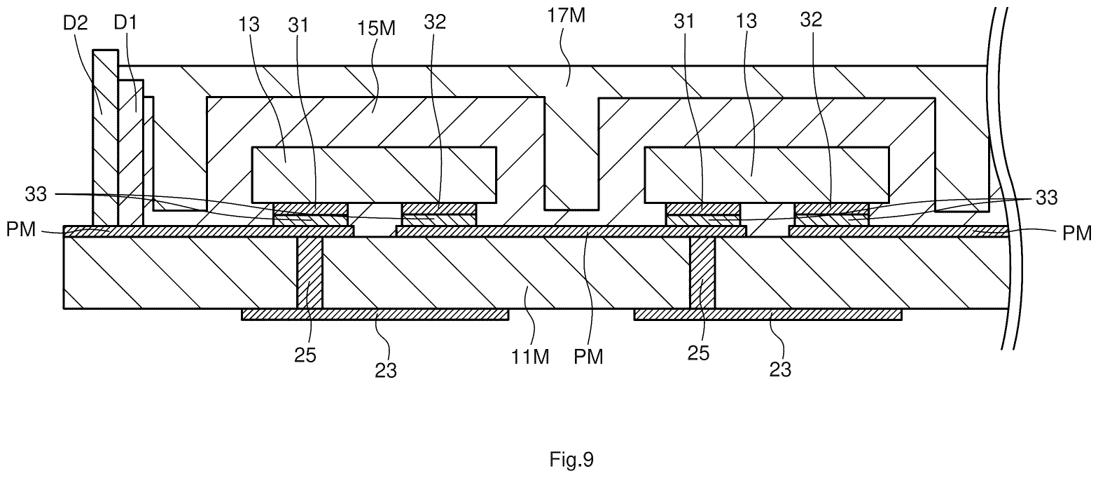

Next, a sealing layer 17M covering the phosphor layer 15M is formed by a pouring and molding method (Step 5: a sealing layer forming step). Specifically, as illustrated in FIG. 9, a frame-shaped second dam structure D2 made of a resin is formed along the outer edge of the substrate assembly 11M to surround the first dam structure D1, and a predetermined amount of a second precursor resin to be the sealing layer 17M is poured inside the second dam structure D2.

This causes the second precursor resin to be filled into the separation trenches 15MG of the phosphor layer 15M. After that, the second precursor resin is left to settle such that it becomes smooth, and then the sealing layer 17M is formed by heat-curing at 150° C. for 120 minutes.

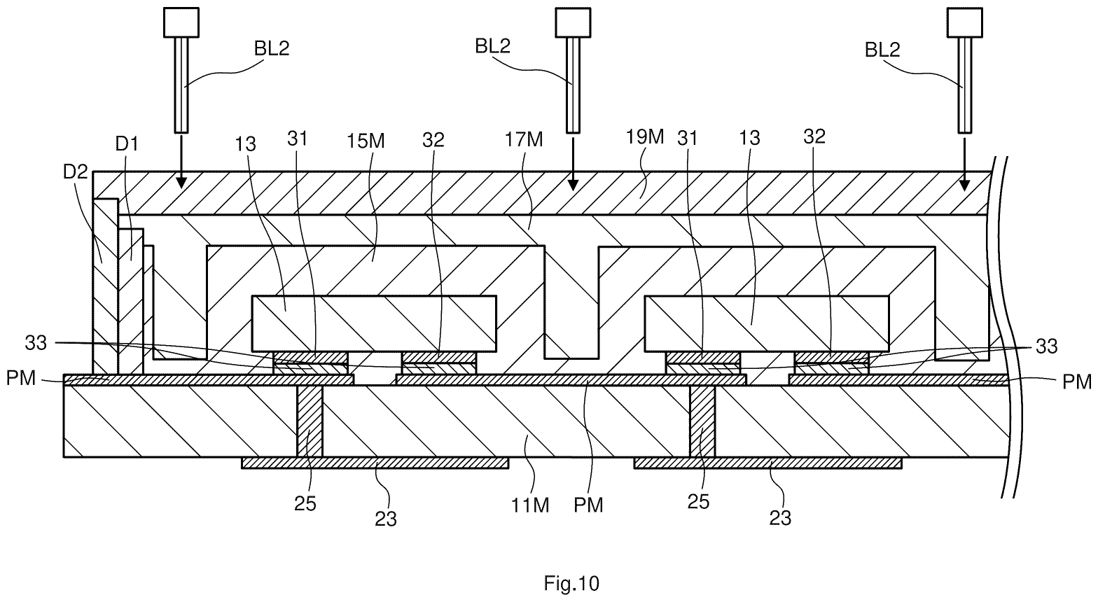

Next, a transmissive-reflective layer 19M, which is a dielectric multilayer film, is formed on an upper surface of the sealing layer 17M (Step 6: a transmissive-reflective layer forming step). Specifically, as illustrated in FIG. 10, the transmissive-reflective layer 19M is formed by alternately stacking Al₂O₃ layer and SiO₂ layer by atomic layer deposition (ALD) such that the reflectivity for the white light is about 60%.

Finally, each of the plurality of light-emitting devices 100 is individualized (Step 7: an individualizing step). Specifically, each of the plurality of light-emitting devices 100 is individualized by cutting along the separation trenches 15MG from the top of the transmissive-reflective layer 19M to the substrate assembly 11M using the dicing blade BL2 of the dicer illustrated in FIG. 10. The light-emitting device 100 can be manufactured by the above-described steps.

The dicing blade BL2 used to individualize the light-emitting devices 100 in Step 7 has a thinner blade than the dicing blade BL1 used to form the separation trenches 15MG in Step 4.

Therefore, when individualizing the light-emitting device 100 using the dicing blade BL2, the force applied to the substrate assembly 11M is decreased. Therefore, the substrate assembly 11M can be cut without causing the substrate assembly 11M to bend.

In the above-described Step 4, the thickness HR of the phosphor layer 15M (Later, the frame-shaped portion 15F) remaining when the separation trenches 15MG are formed is preferred to be greater than a value (D+σ) obtained by adding a standard deviation (σ) to an average grain diameter (D) of the phosphor particles having larger grain diameter of the phosphor particles contained in the phosphor layer 15M.

For example, the average grain diameter of β-sialon phosphor is 16 μm, which is larger than the average grain diameter (D) of KSF Phosphor, and the standard deviation (σ) is 5 μm. Therefore, it is preferred that the thickness HR is 21 μm or more. Also, it is further preferred that it is 26 μm (D+2σ), which is the average grain diameter (D) plus twice the standard deviation (σ), and it is further preferred that it is 31 μm (D+3σ), which is the average grain diameter (D) plus three times the standard deviation (σ).

This is because the phosphor particles are trapped between the wide cutting edge of the dicing blade BL1 and the upper surface of the substrate assembly 11M during the formation of the separation trenches 15MG, and this suppresses cracks from forming in the substrate assembly 11M due to the trapped phosphor particles. Also, in Step 5 (a sealing layer forming step), the second precursor resin to be the sealing layer 17M suppresses the problem of covering the anode electrode 23 and the cathode electrode 24 on the bottom surface through the cracks in the substrate assembly 11M.

When the depth of the separation trench 15MG is shallow, the exposed cross-section of the frame-shaped portion 15F increases when the light-emitting device 100 is made, and the phosphors contained in the phosphor layer 15 may deteriorate due to corrosive gases in the outside air. Therefore, it is preferred that the thickness HR is ⅛ or less of the height HP of the phosphor layer 15. It is even more preferred that it is 1/16 or less of the height HP.

For example, when the height of the phosphor layer 15 is 0.6 mm, the thickness HR is preferred to be 0.075 (75 μm) or less, and 0.038 mm (38 μm) is further preferred. Also, when the height of the phosphor layer 15 is 0.8 mm, the thickness HR is preferred to be 0.1 mm (100 μm) or less, and 0.05 mm (50 μm) is further preferred.

### [Improvement of Yield During Manufacturing of Light-Emitting Device]

As described above, the manufacturing method of the light-emitting device 100 of this embodiment can suppress the phosphor layer 15M from peeling off from the substrate assembly 11M and the light-emitting element 13 from disconnecting by partially leaving the phosphor layer 15 uncut when forming the separation trenches 15MG in Step 4. In other words, this improves the yield during manufacturing. Also, since the formation of cracks in the substrate assembly 11M is suppressed in Step 4, the anode electrode 23 and the cathode electrode 24 are suppressed from being covered by the resin of the sealing layer 17M during the formation of the sealing layer 17M in Step 5. This improves the yield during manufacturing.

Therefore, in the first manufacturing method for the light-emitting device 100 of this embodiment, it becomes difficult for the substrate assembly 11M to become bent or cracked. Therefore, with the first manufacturing method for the light-emitting device 100 of the embodiment, the yield during the manufacturing of the light-emitting device 100 can improve.

### [Manufacturing Method for Light-Emitting Device 100 According to Modification]

Next, the manufacturing method for the light-emitting device 100 according to the modification is described. The manufacturing method for the light-emitting device 100 according to the modification differs from the first manufacturing method described above only in Step 6 (a transmissive-reflective layer forming step), and is the same as the first manufacturing method in all other respects.

In this manufacturing method, the transmissive-reflective layer 19M is formed by the pouring and molding method onto the upper surface of the sealing layer 17M. Specifically, a frame-shaped third dam structure D3 (not illustrated) made of a resin is formed along the outer edge of the substrate assembly 11M to surround the second dam structure D2, and a predetermined amount of a third precursor resin, which is a silicone resin with YPO₄ particles dispersed therein, is poured inside the third dam structure D3. After allowing the third precursor resin to settle such that it becomes smooth, it is heat-cured at 150° C. for 90 minutes to form the transmissive-reflective layer 19M of the light-emitting device 100 according to the modification.

In the manufacturing method, the yield when manufacturing the light-emitting device 100 can be improved because the manufacturing step of the above-described Steps 4 and 5 is not affected, and the phosphor layer 15M, the sealing layer 17M, and the transmissive-reflective layer 19M can be formed using the pouring and molding method.

### [Second Manufacturing Method for Light-Emitting Device 100]

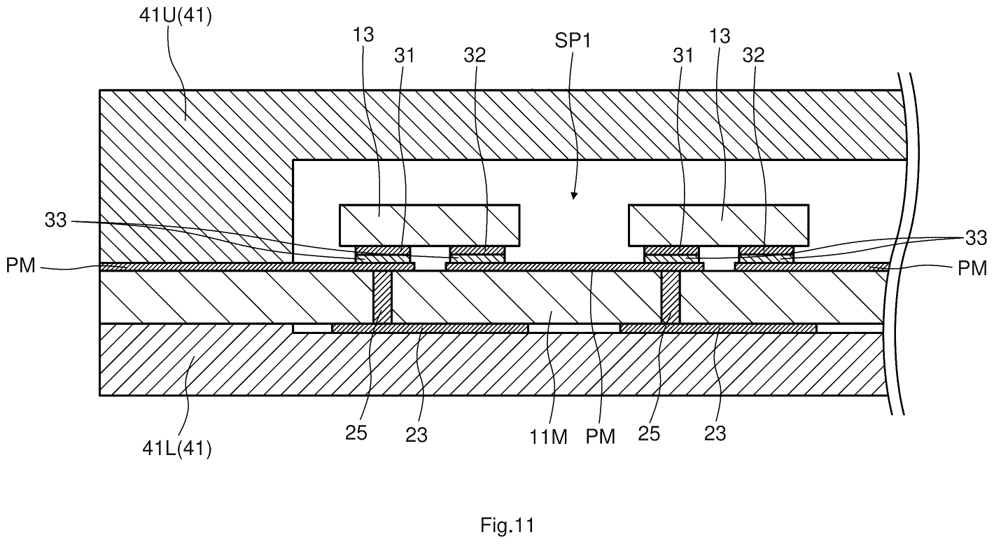

Next, the second manufacturing method for the light-emitting device 100 is described using FIGS. 11 to 14. The second manufacturing method differs from the first manufacturing method in that Step 3 (the phosphor layer forming step), Step 5 (the sealing layer forming step) and Step 6 (the transmissive-reflective layer forming step) described in the first manufacturing method are performed using an insert molding, and the other steps are the same as those in the first manufacturing method.

The following describes each of the steps that differ from the first manufacturing method, Step 3, Step 5, and 6, as Step 3-2, Step 5-2, and Step 6-2, respectively.

### [Step 3-2: Phosphor Layer Forming Step]

In the phosphor layer forming step of the manufacturing method, as illustrated in FIG. 11, a substrate assembly 11M, on which the light-emitting elements 13 are already mounted, is sandwiched by a first mold 41 constituted of an upper mold 41U and a lower mold 41L. The upper mold 41U has a first space SP1 that houses the plurality of light-emitting elements 13 on the upper surface of the substrate assembly 11M.

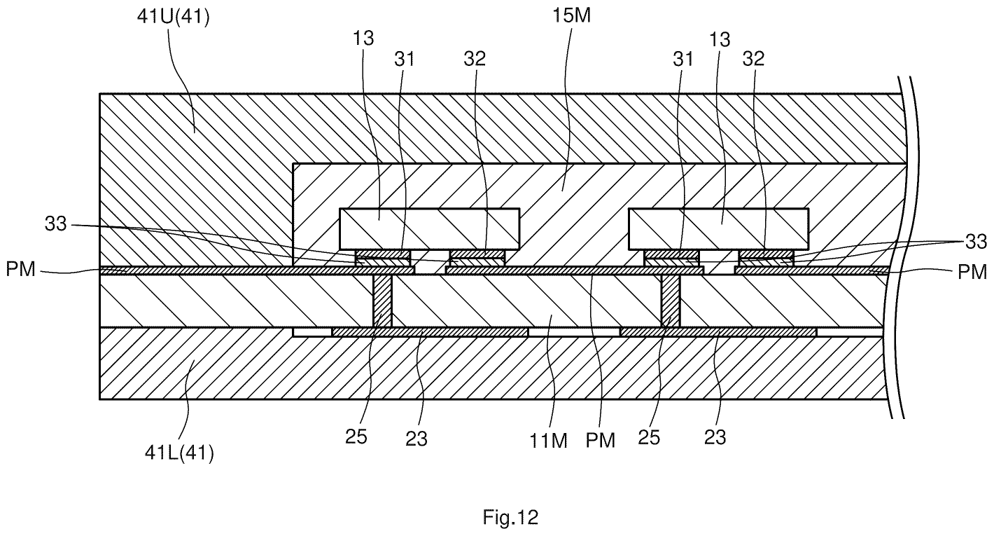

Then, as illustrated in FIG. 12, the above-described first precursor resin is poured into the first space SP1 formed by the first mold 41. After that, the first precursor resin is cured by heating the first mold 41 to the curing temperature to form the phosphor layer 15M.

### [Step 5-2: Sealing Layer Forming Step]

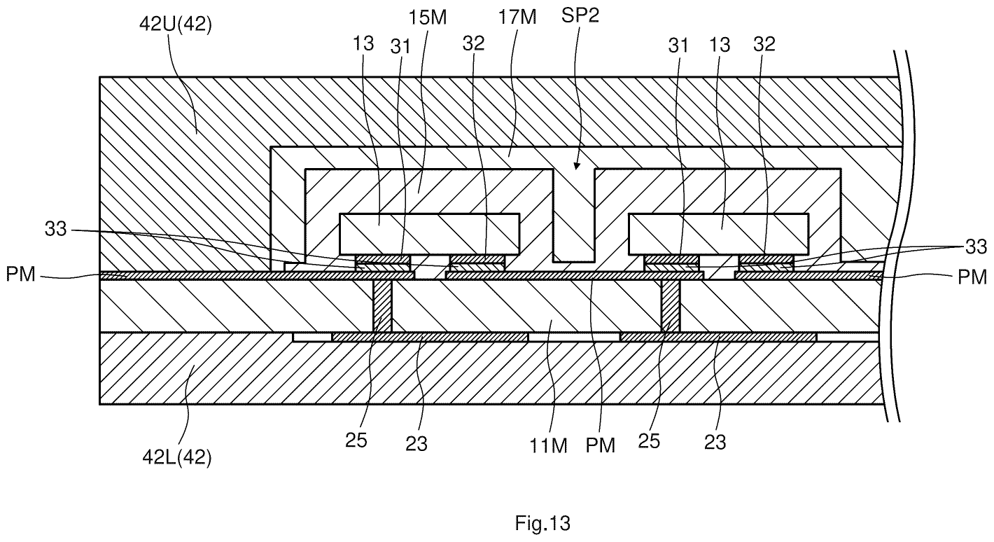

In the sealing layer forming step of the manufacturing method, as illustrated in FIG. 13, the substrate assembly 11M, which has the phosphor layer 15M and the separation trenches 15MG, is sandwiched by a second mold 42 constituted of an upper mold 42U and a lower mold 42L. The upper mold 42U has a second space SP2 that houses the phosphor layer 15M on the upper surface of the substrate assembly 11M.

Then, as illustrated in FIG. 13, the above-described second precursor resin is poured into the second space SP2 formed by the second mold 42. After that, the second precursor resin is cured by heating the second mold 42 to the curing temperature to form the sealing layer 17M.

### [Step 6-2: Transmissive-Reflective Layer Forming Step]

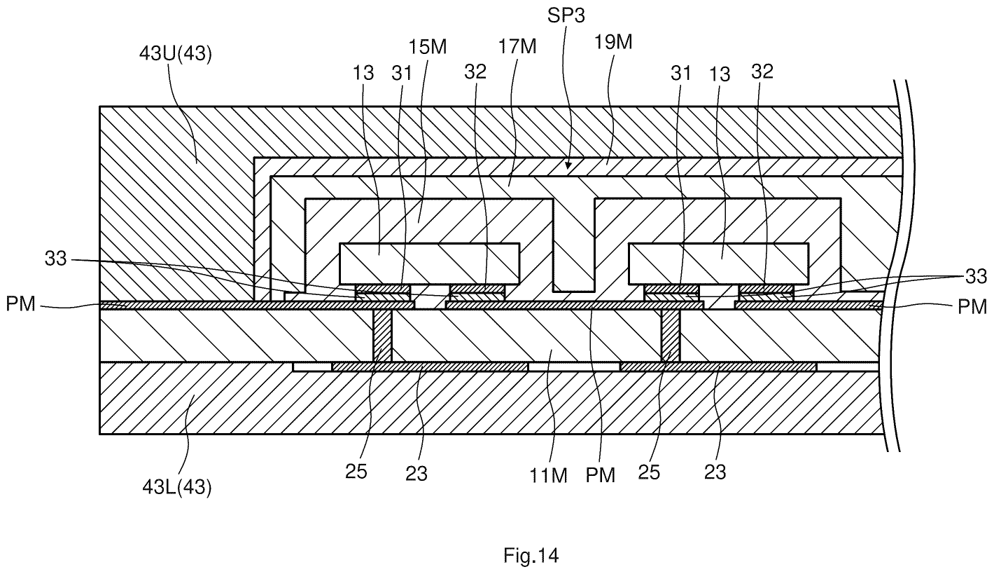

In the transmissive-reflective layer forming step of this manufacturing method, as illustrated in FIG. 14, the substrate assembly 11M, on which the sealing layer 17M is formed, is sandwiched by a third mold 43 constituted of an upper mold 43U and a lower mold 43L. The upper mold 43U has a third space SP3 that houses the sealing layer 17M on the upper surface of the substrate assembly 11M.

Then, as illustrated in FIG. 14, the third precursor resin described in the modification is poured into the third space SP3 formed by the third mold 43. After that, the third precursor resin is cured by heating the third mold 43 to the curing temperature to form the transmissive-reflective layer 19M.

Each of Step 3-2, Step 5-2, and Step 6-2 of the second manufacturing method is to form each layer by so-called insert molding (specifically, a transfer molding or a compression molding). This allows the light-emitting device 100 to be stably mass-produced with high shape accuracy and high manufacturing throughput compared with the first manufacturing method.

In addition, in the second manufacturing method, Step 4 can be provided between Step 3-2 and Step 5-2, which improves the yield when manufacturing the light-emitting device 100. In particular, Step 5-2 of the insert molding, a high-pressure second precursor resin is injected onto the upper surface side of the substrate assembly 11M, on which the phosphor layers 15M and the separation trenches 15MG have been formed. Therefore, the yield during manufacturing can be improved by Step 4, in which the separation trenches 15MG are formed without causing cracks in the substrate assembly 11M.

### [Third Manufacturing Method for Light-Emitting Device 100]

Next, the third manufacturing method for the light-emitting device 100 is described. The third manufacturing method is a manufacturing method in which a part of the steps described in the first manufacturing method is replaced with the steps of the second manufacturing method. Specifically, the third manufacturing method is the same as the first manufacturing method for Step 1 to Step 3, Step 6, and Step 7, and only Step 5 (sealing layer forming step) is replaced with Step 5-2 of the second manufacturing method.

The second precursor resin that forms the sealing layer 17M in Step 5 is a liquid that does not contain any solid. Thus, it is suitable for the insert molding. In addition, since the upper surface of the sealing layer 17M formed by the insert molding is a flat surface with a high precision, it is suitable for forming the transmissive-reflective layer 19M as a dielectric multilayer film.

In other words, in the third manufacturing method, the phosphor layer 15M is formed by the pouring and molding, the sealing layer 17M is formed by the insert molding, and the transmissive-reflective layer 19M is formed by the ALD molding.

The third manufacturing method is a method that combines the pouring and molding of the first manufacturing method and the insert molding of the second manufacturing method. Accordingly, the third manufacturing method of the light-emitting device 100 enables stable mass production while suppressing manufacturing variation of the light-emitting device 100. In other words, the third manufacturing method of the light-emitting device 100 improves the balance between the manufacturing accuracy and the cost compared with the first manufacturing method and the second manufacturing method.

In other words, the third manufacturing method is a manufacturing method suitable for forming the phosphor layer 15M, the sealing layer 17M, and the transmissive-reflective layer 19M, and since it is possible to form a high yield for each manufacturing Step, it is possible to improve the yield when manufacturing the light-emitting device 100.

When individualizing the light-emitting device 100 in Step 7 as described above, it may be cut with the dicing blade BL2 from the underside of the substrate assembly 11M. In this case, the cutting with the dicing blade BL2 is performed using the anode electrode 23 and the cathode electrode 24 formed on the underside of the substrate assembly 11M as markers, which reduces the variation in the external dimensions of the light-emitting device 100.

As described in the above plurality of embodiments, with the present invention, it is possible to improve the yield during the manufacturing of the light-emitting devices 100 while achieving the wide-angle light distribution of the radiated light of the light-emitting devices 100.

It is understood that the foregoing description and accompanying drawings set forth the preferred embodiments of the present invention at the present time. Various modifications, additions and alternative designs will, of course, become apparent to those skilled in the art in light of the foregoing teachings without departing from the spirit and scope of the disclosed invention. Thus, it should be appreciated that the present invention is not limited to the disclosed Examples but may be practiced within the full scope of the appended claims. The present application is based upon and claims the benefit of priority from the prior Japanese Patent Application No. 2024-047130 filed on Mar. 22, 2024, the entire contents of which are incorporated herein by reference.

### DESCRIPTION OF REFERENCE SIGNS

11 Substrate
13 Light-emitting element
15 Phosphor layer
17 Scaling layer
19 Transmissive-reflective layer
21 Anode pad
22 Cathode pad
23 Anode electrode
24 Cathode electrode
25 Conductive via
27 Semiconductor structure layer
28 Light-transmitting substrate
31 p-Electrode
32 n-Electrode
33 Epoxy resin solder

What is claimed is:

1. A manufacturing method for a light-emitting device, comprising
a preparing step of preparing a substrate having an upper surface on which a plurality of light-emitting elements are disposed, each of the plurality of light-emitting elements including a light-emitting layer;
a phosphor layer forming step of forming a phosphor layer by pouring a first precursor made of a resin in which phosphor particles are dispersed onto the upper surface of the substrate and heat-curing the poured first precursor, the phosphor layer encompassing the plurality of light-emitting elements;
a trench forming step of forming a trench on an upper surface of the phosphor layer to separate each of the light-emitting elements in a top view from a direction perpendicular to the upper surface;
a sealing layer forming step of forming a sealing layer by pouring a second precursor made of a translucent resin onto the upper surface of the phosphor layer and heat-curing the poured second precursor;
a transmissive-reflective layer forming step of forming a transmissive-reflective layer on the sealing layer, the transmissive-reflective layer partially reflecting and partially transmitting each of a light emitted from the light-emitting layer and a fluorescence emitted from the phosphor layer; and
an individualizing step of individualizing the light-emitting device by cutting from an upper surface of the transmissive-reflective layer to the substrate along the trench in depth direction.

2. The manufacturing method for the light-emitting device according to claim 1, wherein
a height of a remaining portion of the phosphor layer remaining after forming the trench in the phosphor layer from the upper surface of the substrate is greater than an average grain diameter of the phosphor particles.

3. The manufacturing method for the light-emitting device according to claim 1, comprising:
forming a frame-shaped first dam structure along an outer edge of the substrate on the upper surface of the substrate, and pouring the first precursor into an inside of the first dam structure, in the phosphor layer forming step; and
forming a frame-shaped second dam structure along an outer edge of the first dam structure on the upper surface of the substrate to surround the first dam structure, and pouring the second precursor into an inside of the second dam structure, in the sealing layer forming step.

4. The manufacturing method for the light-emitting device according to claim 1, comprising:
holding the substrate with a first mold to form a first space that houses a plurality of the light-emitting elements on the upper surface of the substrate, and pouring the first precursor into the first space, in the phosphor layer forming step; and
holding the substrate with a second mold to form a second space that houses the phosphor layer, and pouring the second precursor into the second space, in the sealing layer forming step.

5. The manufacturing method for the light-emitting device according to claim 3, comprising:
depositing a dielectric multilayer film by atomic layer deposition to form the transmissive-reflective layer in the transmissive-reflective layer forming step.

6. The manufacturing method for the light-emitting device according to claim 3, wherein
forming a frame-shaped third dam structure along an outer edge of the second dam structure on the upper surface of the substrate to surround the second dam structure, pouring a third precursor resin in which light diffusing particles dispersed inside the third dam structure, and heat-curing the poured third precursor resin to form the transmissive-reflective layer, in the transmissive-reflective layer forming step.

7. The manufacturing method for the light-emitting device according to claim 4, wherein
holding the substrate with a third mold to form a third space that houses the sealing layer, pouring a third precursor resin in which light diffusing particles dispersed inside the third space, and heat-curing the poured third precursor resin to form the transmissive-reflective layer, in the transmissive-reflective layer forming step.

8. The manufacturing method for the light-emitting device according to claim 1, wherein
forming a frame-shaped first dam structure along an outer edge of the substrate on the upper surface of the substrate, and pouring the first precursor into an inside of the first dam structure, in the phosphor layer forming step;
holding the substrate with a second mold to form a second space that houses the phosphor layer, and poring the second precursor in an inside of the second space, in the scaling layer forming step; and
depositing a dielectric multilayer film by atomic layer deposition to form the transmissive-reflective layer, in the transmissive-reflective layer forming step.
